(19) United States
(12) Patent Application Publication
(10) Pub. No.: US 2025/0305889 A1
(43) Pub. Date: Oct. 2, 2025

(54) POWER SEMICONDUCTOR MODULE INCLUDING TEMPERATURE SENSOR

(71) Applicant: HYUNDAI MOBIS CO., LTD., Seoul (KR)

(72) Inventor: Jeong Kwang SEO, Youngins-si (KR)

(73) Assignee: HYUNDAI MOBIS CO., LTD., Seoul (KR)

(21) Appl. No.: 19/015,906

(22) Filed: Jan. 10, 2025

(30) Foreign Application Priority Data
Apr. 1, 2024 (KR) 10-2024-0044134

(51) Int. Cl. G01K 7/22; G01K 1/14

(52) U.S. Cl. CPC G01K 7/22; G01K 1/14

(57) ABSTRACT

The present invention relates to a power semiconductor module including a temperature sensor, and more particularly, to a power semiconductor module including a temperature sensor in which temperature detection efficiency is increased by placing the temperature sensor on a semiconductor device. An object of the present invention is to accurately measure a temperature of a semiconductor device in real time by placing a temperature sensor directly on the semiconductor device.

### CROSS-REFERENCE TO RELATED APPLICATIONS

This application claims priority under 35 U.S.C. § 119 to Korean Patent Application No. 10-2024-0044134, filed on Apr. 1, 2024, in the Korean Intellectual Property Office, the disclosure of which is incorporated herein by reference in its entirety.

### TECHNICAL FIELD

The following disclosure relates to a power semiconductor module including a temperature sensor, and more particularly, to a power semiconductor module including a temperature sensor in which temperature detection efficiency is increased by placing the temperature sensor on a semiconductor device.

### BACKGROUND

In a power semiconductor module, a power semiconductor device and a control semiconductor device are integrated into one package. The power semiconductor device is a silicon-controlled rectifier (SCR), a power transistor (MOSFET), an SiC, an insulated-gate bipolar transistor (IGBT), a power regulator, an inverter, or a converter. Such a semiconductor device, unlike a low-voltage device such as a memory device, operates at a high voltage of 30 V to 1000 V or higher, and thus, requires excellent heat dissipation capability and high-voltage insulation capability. In order to thermally stabilize the power semiconductor module, it is necessary to accurately detect a temperature of the semiconductor device.

To this end, conventionally used methods include a method in which a temperature at a portion where a semiconductor device is bonded is directly sensed by inserting a temperature sensing pad at the time of designing the semiconductor device, and a method in which a temperature of a semiconductor device is indirectly sensed by attaching a surface mount technology (SMT)-type thermistor onto a substrate.

The former method has a problem, from the viewpoint of the semiconductor device, in that conduction loss occurs because the active area of the semiconductor device decreases. In addition, there is also a problem, from the viewpoint of the module, in that it is required to provide a separate method for sensing a temperature in a case where a semiconductor device is used with no temperature sensing pad.

In the latter method, a temperature sensor, such as an NTC thermistor, is generally placed on one side of a substrate of a power semiconductor module to indirectly detect a temperature of a semiconductor device adjacent thereto. However, this method has a limit in detecting a temperature of the semiconductor device in real time because it takes time to transmit the temperature of the semiconductor device through the ceramic substrate, and has a problem in that a temperature of a portion where the semiconductor device is connected and a temperature detected by the NTC temperature sensor may be different because of power applied to the semiconductor device.

### SUMMARY

An object of the present invention is to accurately measure a temperature of a semiconductor device in real time by placing a temperature sensor directly on the semiconductor device.

In one general aspect, a power semiconductor module includes: a substrate including one or more copper parts; a semiconductor device electrically bonded to each of the copper parts; a copper clip of which one side is bonded to an upper surface of the semiconductor device and the other side is bonded to another copper part adjacent to the copper part including the semiconductor device to electrically connect the different copper parts; and a temperature sensor configured to detect a temperature of the semiconductor device, wherein the temperature sensor is connected to an upper end of the copper clip.

The temperature sensor may be bonded onto one side of the copper clip bonded to the upper surface of the semiconductor device.

The temperature sensor may have a size smaller than an area of one side of the copper clip bonded to the semiconductor device.

The temperature sensor may be bonded onto one side of the copper clip by soldering.

The semiconductor device may include at least one of an SiC, a MOSFET, and an IGBT.

The copper clip may be formed in a plate type or in a type in which a plurality of wires are combined.

The temperature sensor may include a chip-type NTC thermistor.

According to the present invention, it is possible to directly detect a heating temperature of the semiconductor device of the power semiconductor module.

In addition, according to the present invention, since the temperature of the semiconductor device is directly detected, it is possible to increase temperature detection accuracy.

In addition, according to the present invention, since the accuracy in detecting the temperature of the semiconductor device is increased, it is possible to drive the semiconductor device with increased current specifications according to temperature specifications.

In addition, according to the present invention, since the current specifications can be adjusted according to the temperature specifications of the semiconductor device, it is possible to maximize the operating efficiency of the semiconductor device.

### BRIEF DESCRIPTION OF THE DRAWINGS

FIG. 1 is a plan view illustrating a configuration of a power semiconductor module according to an embodiment of the present invention.

FIG. 2 is a plan view illustrating a semiconductor device region of a power semiconductor module according to an embodiment of the present invention.

FIG. 3 is a longitudinal cross-sectional view illustrating a cross section of a power semiconductor module according to an embodiment of the present invention.

### DETAILED DESCRIPTION OF MAIN ELEMENTS

100: Power semiconductor module
110: Substrate
111: Copper part
120: Semiconductor device
130: Copper clip
140: Temperature sensor

### DETAILED DESCRIPTION

The aforementioned objects, features, and advantages of the present invention will be more apparent from the embodiments to be described below with reference to the accompanying drawings. The following specific structural or functional descriptions are provided merely for the purpose of describing embodiments according to the concept of the present invention, and the embodiments according to the concept of the present invention can be implemented in various forms and should not be construed as being limited to the embodiments set forth herein. Since various modifications may be made to the embodiments according to the concept of the present invention, and the embodiments of the present invention may have various forms, specific embodiments will be illustrated in the drawings and described in detail hereinbelow. However, this is not intended to limit the embodiments according to the concept of the present invention to specific forms disclosed herein, and it should be noted that the specific embodiments described herein cover all modifications, equivalents, or substitutes within the spirit and technical scope of the present invention. Terms “first”, “second”, and/or the like may be used to describe various components, but the components are not limited by the above terms. The above terms are only used to distinguish one component from another component. For example, a first component may be referred to as a second component, and similarly, a second component may be referred to as a first component, without departing from the scope according to the concept of the present invention. It should be noted that, when one component is referred to as being coupled or connected to another component, they may be directly coupled or connected to each other, or they may be coupled or connected to each other through an intervening component therebetween. On the other hand, when one component is referred to as being directly coupled to or directly connected to another component, there is no intervening component therebetween. Other expressions for describing relationships between components, that is, expressions such as “between”, “immediately between”, “adjacent to”, and “directly adjacent to” shall be construed in a similar way. Terms used herein are used only to describe the specific embodiments and are not intended to limit the present invention. Singular expressions include plural expressions unless the context clearly indicates otherwise. It should be noted that terms “include”, “have”, and the like used herein are intended to specify the presence of stated features, numbers, steps, operations, components, parts, or combinations thereof but do not preclude the presence or addition of one or more other features, numbers, steps, operations, components, parts, or combinations thereof. Unless otherwise defined, all terms used herein, including technical or scientific terms, have the same meanings as those generally understood by those skilled in the art to which the present invention pertains. The terms defined in generally used dictionaries and the like should be interpreted as having the same meanings as those in the context of the related art, and should not be interpreted as having ideal or excessively formal meanings unless clearly defined herein. Hereinafter, the present invention will be described in detail by describing preferred embodiments of the present invention with reference to the accompanying drawings. Like reference signs in the drawings indicate like elements.

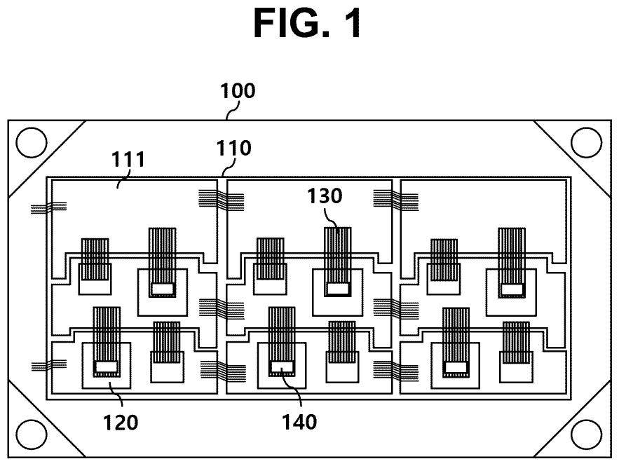

FIG. 1 is a plan view illustrating a configuration of a power semiconductor module according to an embodiment of the present invention.

Referring to FIG. 1, the power semiconductor module 100 according to an embodiment of the present invention may include a substrate 110, a copper part 111, a semiconductor device 120, a copper clip 130, and a temperature sensor 140.

The substrate 110 may include a plurality of copper parts 111 to provide a base for electrically connecting a plurality of semiconductor devices 120 thereto. The substrate 110 may be generally formed of a ceramic material, and the copper parts 111 formed of copper may be coupled (or bonded) to a lower end and an upper end thereof. The plurality of copper parts 111 may be formed to be adjoining but spaced apart from each other, and a device other than the semiconductor device 120 may be electrically coupled or bonded to each of the copper parts 111.

The semiconductor device 120 may be electrically coupled or bonded to each of the copper parts 111 formed on the substrate 110. In general, the semiconductor device 120 may be coupled or bonded to an upper surface of the copper part 111 by soldering. The semiconductor device 120 may include at least one of an SiC, a MOSFET, and an IGBT.

One side of the copper clip 130 may be coupled or bonded to the upper surface of the semiconductor device 120, and the other side of the copper clip 130 may be coupled or bonded to another copper part 111 adjacent to the copper part 111 including the semiconductor device 120 to electrically connect the different copper parts 111. The copper clip 130 may be formed of copper, and may be a plate type or in a type in which a plurality of wires are combined. In addition, the copper clip 130 may be coupled or bonded to the upper surface of the semiconductor device 120 and the copper part 111 by soldering. In addition, the copper clip 130 may be coupled or bonded over more than half of the area of the upper surface of the semiconductor device 120 to increase the efficiency of the electrical connection.

The temperature sensor 140 may be coupled or bonded to an upper end of the copper clip 130 to detect a temperature of the semiconductor device 120, from which heat is generated in the power semiconductor module 100. The temperature sensor 140 may include, for example, an NTC thermistor, or may include any other sensor capable of detecting a temperature. The temperature sensor 140 may be coupled or bonded onto one side of the copper clip 130 coupled or bonded to the upper surface of the semiconductor device 120 to more accurately measure a temperature of the semiconductor device 120. That is, heat generated from the semiconductor device 120 is transferred through the copper clip 130, which has high thermal conductivity, so that the temperature sensor 140 can measure a temperature of the semiconductor device 120 more accurately and efficiently.

In addition, in order to accurately bond the temperature sensor 140 to the upper end of the copper clip 130, the temperature sensor 140 may be a sensor having a size smaller than the area of one side of the copper clip 130 coupled or bonded to the semiconductor device 120. In addition, the temperature sensor 140 may be coupled or bonded to the upper end of the copper clip 130, including a chip-type NTC thermistor, so as not to increase the overall volume of the power semiconductor module 100. In addition, the temperature sensor 140 may also be coupled or bonded to the upper end of the copper clip 130 by soldering.

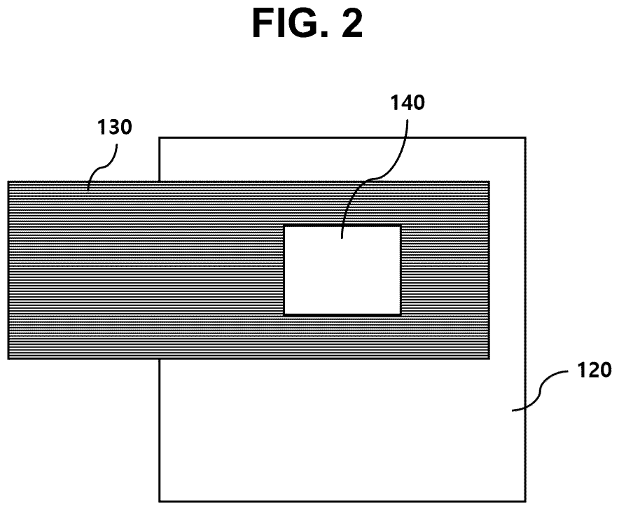

FIG. 2 is a plan view illustrating a semiconductor device region of a power semiconductor module according to an embodiment of the present invention.

Referring to FIG. 2, the power semiconductor module 100 according to the present invention may include a semiconductor device 120, a copper clip 130 may be coupled or bonded onto the semiconductor device 120, and a temperature sensor 140 may be coupled or bonded onto the copper clip 130.

As illustrated in FIG. 2, one side of the copper clip 130 may be bonded to the upper surface of the semiconductor device 120, and the other side of the copper clip 130 may be coupled or bonded to another copper part 111 adjacent to the copper part 111 including the semiconductor device 120 to electrically connect the different copper parts 111. The copper clip 130 may be formed of copper, and may be a plate type or in a type in which a plurality of wires are combined. In addition, the copper clip 130 may be coupled or bonded to the upper surface of the semiconductor device 120 and the copper part 111 by soldering. In addition, the copper clip 130 may be coupled or bonded over more than half of the area of the upper surface of the semiconductor device 120 to increase the efficiency of the electrical connection.

As illustrated in FIG. 2, the temperature sensor 140 may be coupled or bonded to an upper end of the copper clip 130 to detect a temperature of the semiconductor device 120, from which heat is generated in the power semiconductor module 100. The temperature sensor 140 may include, for example, an NTC thermistor, or may include any other sensor capable of detecting a temperature. The temperature sensor 140 may be coupled or bonded onto one side of the copper clip 130 coupled or bonded to the upper surface of the semiconductor device 120 to more accurately measure a temperature of the semiconductor device 120. That is, heat generated from the semiconductor device 120 is transferred through the copper clip 130, which has high thermal conductivity, so that the temperature sensor 140 can measure a temperature of the semiconductor device 120 more accurately and efficiently.

In addition, in order to accurately bond the temperature sensor 140 to the upper end of the copper clip 130, the temperature sensor 140 may be a sensor having a size smaller than the area of one side of the copper clip 130 coupled or bonded to the semiconductor device 120. In addition, the temperature sensor 140 may be coupled or bonded to the upper end of the copper clip 130, including a chip-type NTC thermistor, so as not to increase the overall volume of the power semiconductor module 100. In addition, the temperature sensor 140 may also be coupled or bonded to the upper end of the copper clip 130 by soldering.

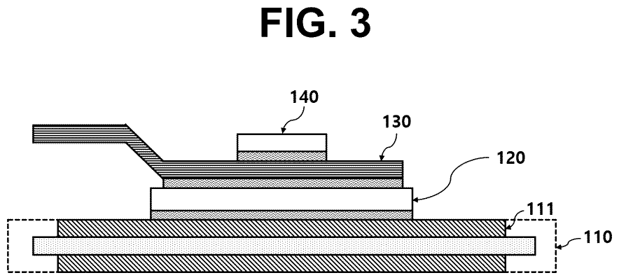

FIG. 3 is a longitudinal cross-sectional view illustrating a cross section of a power semiconductor module according to an embodiment of the present invention.

Referring to FIG. 3, the power semiconductor module 100 according to the present invention may include a substrate 110, a copper part 111, a semiconductor device 120, a copper clip 130, and a temperature sensor 140.

The substrate 110 may include one or more copper parts 111 to provide a base for electrically connecting a plurality of semiconductor devices 120 thereto. The substrate 110 may be generally formed of a ceramic material, and the copper parts 111 formed of copper may be coupled or bonded to a lower end and an upper end thereof. The plurality of copper parts 111 may be formed to be spaced apart from each other, and a device other than the semiconductor device 120 may be electrically coupled or bonded to each of the copper parts 111.

The semiconductor device 120 may be electrically coupled or bonded to each of the copper parts 111 formed on the substrate 110. In general, the semiconductor device 120 may be coupled or bonded to an upper surface of the copper part 111 by soldering. The semiconductor device 120 may include at least one of an SiC, a MOSFET, and an IGBT.

One side of the copper clip 130 may be coupled or bonded to the upper surface of the semiconductor device 120, and the other side of the copper clip 130 may be coupled or bonded to another copper part 111 adjacent to the copper part 111 including the semiconductor device 120 to electrically connect the different copper parts 111. The copper clip 130 may be formed of copper, and may be a plate type or in a type in which a plurality of wires are combined. In addition, the copper clip 130 may be coupled or bonded to the upper surface of the semiconductor device 120 and the copper part 111 by soldering. In addition, the copper clip 130 may be coupled or bonded over more than half of the area of the upper surface of the semiconductor device 120 to increase the efficiency of the electrical connection.

The temperature sensor 140 may be coupled or bonded to an upper end of the copper clip 130 to detect a temperature of the semiconductor device 120, from which heat is generated in the power semiconductor module 100. The temperature sensor 140 may include, for example, an NTC thermistor, or may include any other sensor capable of detecting a temperature. The temperature sensor 140 may be coupled or bonded onto one side of the copper clip 130 coupled or bonded to the upper surface of the semiconductor device 120 to more accurately measure a temperature of the semiconductor device 120. That is, heat generated from the semiconductor device 120 is transferred through the copper clip 130, which has high thermal conductivity, so that the temperature sensor 140 can measure a temperature of the semiconductor device 120 more accurately and efficiently.

In addition, in order to accurately bond the temperature sensor 140 to the upper end of the copper clip 130, the temperature sensor 140 may be a sensor having a size smaller than the area of one side of the copper clip 130 coupled or bonded to the semiconductor device 120. In addition, the temperature sensor 140 may be coupled or bonded to the upper end of the copper clip 130, including a chip-type NTC thermistor, so as not to increase the overall volume of the power semiconductor module 100. In addition, the temperature sensor 140 may also be coupled or bonded to the upper end of the copper clip 130 by soldering.

Although the preferred embodiments of the present invention have been described above, the embodiments disclosed herein are not intended to limit the technical idea of the present invention, but are provided to explain the technical idea of the present invention. Therefore, the technical idea of the present invention includes not only each of the embodiments disclosed herein but also a combination of the embodiments disclosed here, and furthermore, the scope of the technical idea of the present invention is not limited by these embodiments. In addition, those skilled in the art to which the present invention pertains may make various changes and modifications to the present invention without departing from the spirit and scope of the appended claims, and all of such appropriate changes and modifications shall be regarded as falling within the scope of the present invention as equivalents.

What is claimed is:

1. A power semiconductor module comprising:
a substrate including first and second copper parts adjoining each other;
a semiconductor device electrically coupled to the first copper parts;
a copper clip having a first end coupled to an upper surface of the semiconductor device and a second end coupled to the second copper part, the copper clip configured to electrically connect the first and second copper parts; and
a temperature sensor connected to an upper end of the copper clip and configured to detect a temperature of the semiconductor device.

2. The power semiconductor module of claim 1, wherein the temperature sensor is coupled to a side of the copper clip.

3. The power semiconductor module of claim 2, wherein the temperature sensor has a size smaller than an area of the side of the copper clip.

4. The power semiconductor module of claim 3, wherein the temperature sensor is coupled to the side of the copper clip by soldering.

5. The power semiconductor module of claim 1, wherein the semiconductor device includes at least one of an SiC, a MOSFET, and an IGBT.

6. The power semiconductor module of claim 1, wherein the copper clip is a plate type or a type in which a plurality of wires are combined.

7. The power semiconductor module of claim 1, wherein the temperature sensor includes a chip-type NTC thermistor.
